(19) United States
(12) Patent Application Publication
(10) Pub. No.: US 2012/0198292 A1
(43) Pub. Date: Aug. 2, 2012

(54) TEST APPARATUS AND TEST METHOD

(75) Inventors: Akimasa YUZURIHARA, Tokyo (JP); Daisuke MAKITA, Tokyo (JP); Tsuneaki KANAZAWA, Kanagawa (JP); Hidekazu NAKAI, Kanagawa (JP); Shinichiro YUKAWA, Kanagawa (JP); Daisuke SAKAMAKI, Tokyo (JP); Toshihiko ARAI, Kanagawa (JP)

(73) Assignee: ADVANTEST CORPORATION, Tokyo (JP)

(21) Appl. No.: 13/365,272

(22) Filed: Feb. 3, 2012

Related U.S. Application Data
(63) Continuation of application No. PCT/JP2011/000852, filed on Feb. 16, 2011.

(30) Foreign Application Priority Data
Apr. 19, 2010 (JP) 2010-096281

(51) Int. Cl. G11C 29/00; G06F 11/26

(52) U.S. Cl. 714/718; 714/E11.159

(57) ABSTRACT

Provided is a test apparatus that tests a memory under test, comprising a testing integrated circuit device that tests the memory under test and includes an internal memory storing test information including at least one of a test result and test data for a partial memory region of the memory under test; an external memory that stores the test information for an entire memory region of the memory under test; and a memory controller that is connected to the external memory and transmits test information for a memory region of a test target between the external memory and the internal memory. Also provided is a test method.

### BACKGROUND

1. Technical Field

The present invention relates to a test apparatus and a test method.

2. Related Art

Conventionally, a memory test apparatus is connected to a plurality of memories under test, which are devices under test (DUT), and tests the plurality of memories in parallel, as described in Patent Documents 1 and 2, for example.

Patent Document 1: Japanese Patent Application Publication No. H07-130200

### Patent Document 2: Japanese Patent Application Publication No. 2006-318577

However, since the capacity of the memories under test serving as the testing targets has been increasing, the test apparatus must handle a large amount of test pattern data and fail data, for example. Accordingly, the testing sections that transmit the test pattern data and the fail data to the memories under test must each have a large memory capacity.

### SUMMARY

Therefore, it is an object of an aspect of the innovations herein to provide a test apparatus and a test method, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a test apparatus that tests a memory under test, comprising a testing integrated circuit device that tests the memory under test and includes an internal memory storing test information including at least one of a test result and test data for a partial memory region of the memory under test; an external memory that stores the test information for an entire memory region of the memory under test; and a memory controller that is connected to the external memory and transmits test information for a memory region of a test target between the external memory and the internal memory. Also provided is a test method.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a test apparatus 100 according to an embodiment of the present invention, along with memories under test 10.

FIG. 2 shows an exemplary configuration of a test board 150 according to the present embodiment.

FIG. 3 shows an operational flow of the test apparatus 100 according to the present embodiment.

FIG. 4 shows a process flow of a modification of the test apparatus 100 according to the present embodiment.

FIG. 5 shows timings of the processing in the present modification of the test apparatus 100 according to the present embodiment, with the time axis as the horizontal axis.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

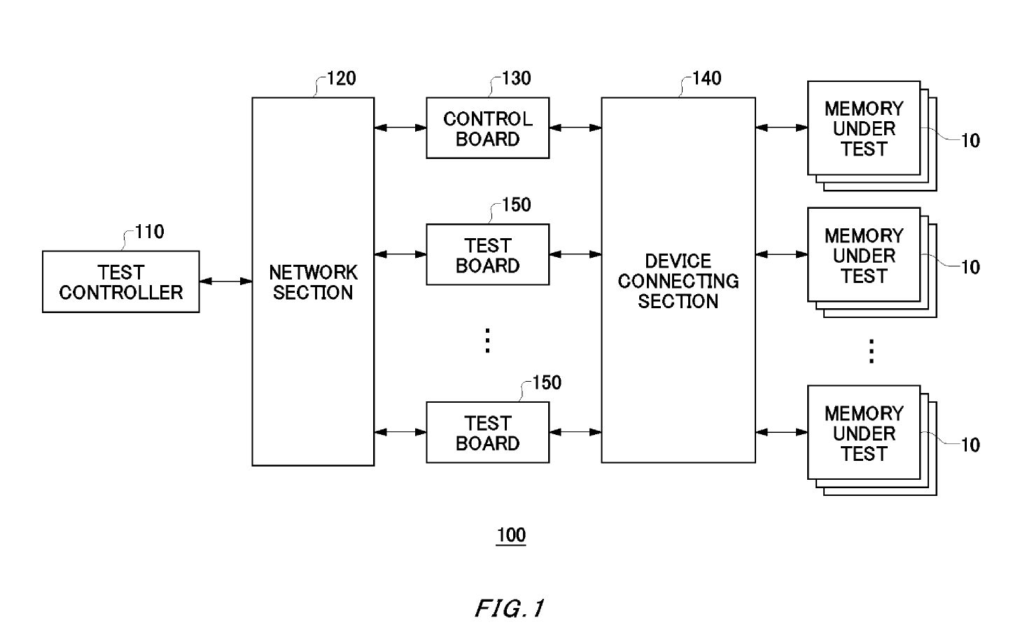

FIG. 1 shows an exemplary configuration of a test apparatus 100 according to an embodiment of the present invention, along with memories under test 10. The test apparatus 100 tests at least one memory under test 10, which may be a flash memory, a memory housed in a multi-chip package (MCP) device, or a memory used in a system on chip (SOC). The test apparatus 100 tests the memories under test 10 while transmitting test information containing at least one of test data used for testing and test results between internal memories included respectively in testing sections and external memories included respectively in test sites. In this way, the test apparatus 100 can test a large number of memories under test while keeping the amount of internal memory in each testing section low.

The test apparatus 100 includes a test controller 110, a network section 120, a control board 130, a device connecting section 140, and test boards 150. The test controller 110 is connected to the control board 130 and the plurality of test boards 150, and controls the testing by the test boards 150. More specifically, the test controller 110 may acquire a test program used for testing from a storage apparatus or a computer outside of a work station, for example, or may receive a test program input by a user, and may execute the program to control operation of the control board 130 and the test boards 150.

The test controller 110 may transmit test information, test sequences, and/or control commands designated by the test program to the corresponding test boards 150 or control board 130 via the network section 120. Furthermore, the test controller 110 may read test results from the test boards 150, for example. In this way, the test controller 110 can display the test results of the memories under test 10 to the user and change the content of the next testing according to the test results.

The network section 120 connects the test controller 110, the control board 130, and the test boards 150 to each other to enable communication. The network section 120 may connect the test controller 110, the control board 130, and the test boards 150 to each other through a universal or specialized interface, and may transmit communication packets therebetween. The network section 120 may use a universal parallel interface or a high-speed serial interface, such as Ethernet (Registered Trademark), USB, or Serial Rapid IO.

The control board 130 supplies a power supply voltage to each test board 150. The control board 130 also controls each of the test boards 150. The control board 130 may control the supply of power to the memories under test 10 and turn ON and OFF switches that provide connections and disconnections between the memories under test 10 and the test boards 150. The control board 130 may instruct the device connecting section 140 to connect the test boards 150 to the memories under test 10 according to the content or type of testing. The control board 130 may instruct the device connecting section 140 to connect a plurality of the test boards 150 to a plurality of the memories under test 10 according to the type and number of memories under test 10 and test boards 150. The test apparatus 100 may include a plurality of control boards 130.

The device connecting section 140 connects the control board 130, the test boards 150, and the memories under test 10 to each other in a manner to enable communication. The device connecting section 140 may instruct the control board 130 to turn ON and OFF switches creating connections between the control board 130, the test boards 150, and the memories under test 10. The device connecting section 140 may include a motherboard and a socket, for example. The device connecting section 140 may connect the test boards 150 and the memories under test 10 mounted on sockets to each other via the motherboard in a manner to enable communication.

The test boards 150 test the memories under test 10 based on test patterns, test sequences, and control commands, for example, from the test controller 110. A plurality of the same type of test boards 150 corresponding to the number of memories under test 10 being tested simultaneously may be mounted on the test apparatus 100. Each test board 150 may be connected to one or more of the memories under test 10 via the device connecting section 140.

Each test board 150 may be detachable from the test apparatus 100. The test boards 150 supply test signals to the memories under test 10 via the device connecting section 140, and receive response signals from the memories under test 10. A plurality of control boards 130 and test boards 150 may be housed within a test head, which serves as the main body of the test apparatus 100, for example.

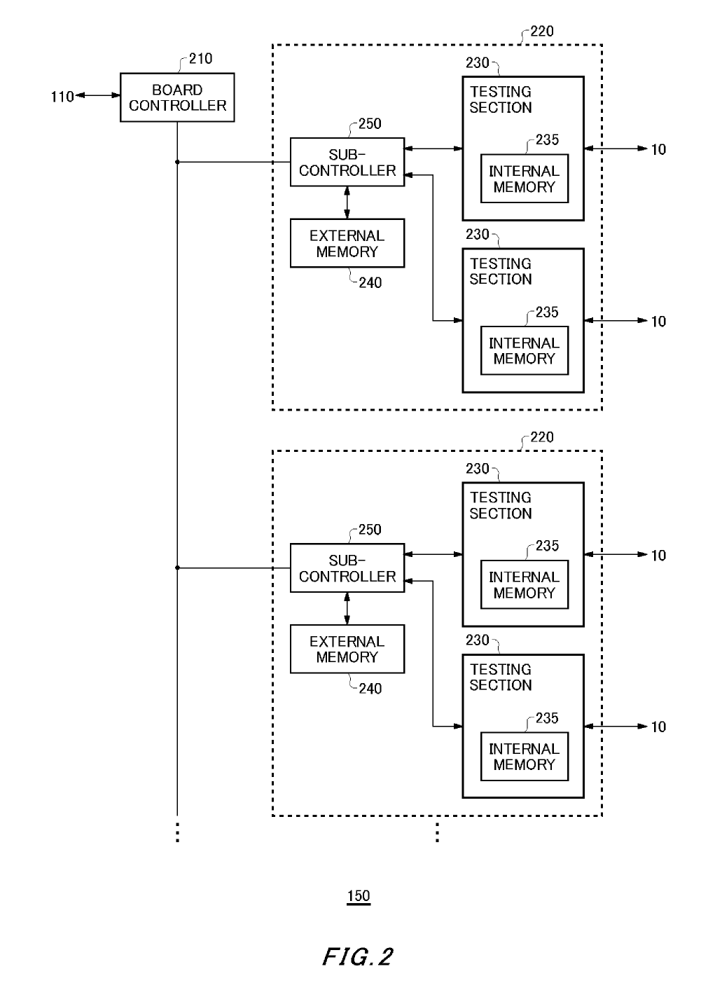

FIG. 2 shows an exemplary configuration of a test board 150 according to the present embodiment. The test board 150 includes a board controller 210 and test sites 220. The board controller 210 receives test information, test sequences, and/or control commands, for example, transmitted by the test controller 110, and transmits the test sequences and/or control commands, for example, to the test site 220 that is to perform testing. The board controller 210 transmits test information including at least one of test data used for testing and test results, control commands such as test start, test end, and test interrupt, and/or a test sequence to each test site 220 that is to perform testing.

Each test site 220 is connected to one or more memories under test 10, and tests the connected memories under test 10 using expected value data and test pattern data, for example, transmitted from the board controller 210, according to the control commands transmitted from the board controller 210. Each test site 220 includes a testing section 230, an external memory 240, and a sub-controller 250. When testing a plurality of memories under test 10, each test site 220 may include a number of testing sections 230 equal to the number of memories under test 10 being tested.

Each testing section 230 functions as a testing integrated circuit device, and tests one memory under test 10. Each testing section 230 includes an internal memory 235. The internal memory 235 stores the test information including at least one of test data and test results corresponding to a partial memory region of the memory under test 10. The internal memory 235 may have a capacity sufficient for storing the data used for testing the partial memory region of the memory under test 10.

Each external memory 240 stores test information corresponding to the entire memory regions of the memories under test 10 connected to the test site 220. Here, the test information may be expected value data and test pattern data, which is test data, test results, or pattern fail data, for example. When testing each memory under test 10 connected to a test site 220 using the same test pattern data, the test information to be stored may be provided in common to the memories under test 10, thereby allowing the external memory 240 to have lower storage capacity.

Each sub-controller 250 functions as a memory controller, is connected to the corresponding external memory 240, and transmits test information corresponding to the memory region of the test target between the external memory 240 and the corresponding internal memories 235. Specifically, the sub-controller 250 receives the data from the test controller 110 via the board controller 210, and stores the received data in the external memory 240. The sub-controller 250 transmits the data stored in the external memory 240 to the internal memories 235. The sub-controller 250 returns the test results stored in the internal memories 235 to the external memory 240.

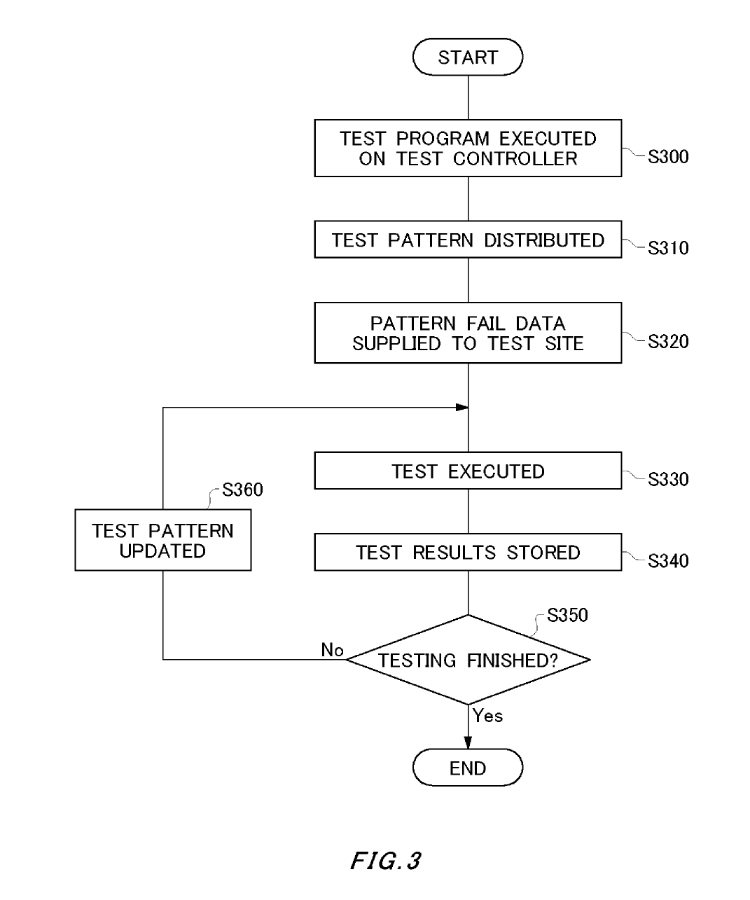

FIG. 3 shows an operational flow of the test apparatus 100 according to the present embodiment. The test controller 110 executes a test program (S300). The test controller 110 transmits to the control board 130 and the test boards 150 test information including test pattern data, expected value data, and pattern fail data, for example, designated by the test program. Furthermore, the control board 130 may instruct the device connecting section 140 to provide connections between the test boards 150 and the memories under test 10, according to the test to be performed.

The board controller 210 transmits test information to be used by each connected test site 220, from among the test information received from the test controller 110, to each connected test site 220. Here, the test controller 110 may attach header information corresponding to the connections between the test boards 150 and the memories under test 10 to the test information, such that the board controller 210 transmits the test information to be used by each test site correctly to the test site 220 to be used by the test board 150.

The one or more testing sections 230 in each test site 220 store the test information transmitted by the board controller 210 in the external memory. Each testing section 230 transmits to the corresponding internal memory 235 a portion of the test information stored in the external memory (S310). Each testing section 230 accesses the external memory 240 via the sub-controller 250. Each testing section 230 may store in the internal memory 235 the test pattern data to be used for the partial memory region of the memory under test 10 on which the first testing is to be performed. Each testing section 230 may also store expected value data, which is test information, in the external memory in the same manner as the test pattern data, and transmit a portion of the test pattern data to the internal memory 235.

If the test apparatus 100 performs a fail analysis in addition to judging pass/fail of the memories under test 10, for example, the test apparatus 100 supplies the test sites 220 with pattern fail data as test information (S320). The pattern fail data may be data including fail information of the memories under test 10 and address information at which the fails occurred, and may indicate whether there is a fail at each bit, word, sector, or block in the memories under test 10, for example. Each testing section 230 may store the pattern fail data in the external memory 240 and transmit to the internal memory 235 the pattern fail data including the fail data of the partial memory region of the memory under test 10 for the first testing.

The above describes an example in which the test apparatus 100 supplies the pattern fail data to the testing sections 230, but instead, the testing sections 230 may clear a region of the external memories 240 storing the pattern fail data, and each testing section 230 may store the pattern fail data for each block in the internal memory 235 each time testing is performed for a predetermined block and transmit the pattern fail data to the external memory 240.

Next, the testing sections 230 test each predetermined block of the memories under test 10 using the expected value data and test pattern data stored in the internal memories 235 (S330). Each testing section 230 obeys a test sequence designated by the test program, to read and write test pattern data to and from the memory under test 10 according to a control signal. Each testing section 230 compares the expected value data to the test pattern data read from the memory under test 10 and judges pass/fail of the memory under test 10 based on whether the comparison indicates a match.

The testing sections 230 store the test results, which are pass/fail judgment results of the memories under test 10 (S340). Each internal memory 235 stores the test results corresponding to the partial memory region of the memory under test 10, and each sub-controller 250 acquires the test results corresponding to the partial memory region from the internal memory 235 and stores the test results in the external memory 240. In this way, each testing section 230 can transmit the test results to the corresponding external memory 240.

Here, when a fail analysis or the like is performed and the comparison results indicate a mismatch for a testing section 230, the testing section 230 reads the pattern fail data from the external memory 240, updates the fail information, and stores the updated fail information in the internal memory 235. The sub-controller 250 reads the updated fail data from the internal memory 235, and writes this data back to the external memory 240. In this way, the testing section 230 can update the fail data and transmit the updated fail data to the external memory 240.

When it has been determined in advance for a testing section 230 that the partial region of the memory under test 10 is a defective region or an unused region, the testing section 230 may record this region as a fail block and skip testing of this region. The external memory 240 stores block fail data indicating pass/fail of each block in the memory under test 10, the sub-controller 250 reads the block fail data for the block to be tested from the external memory 240 and transmits the block fail data to the internal memory 235, and the testing section 230 identifies fail blocks that have already been detected as fails from the block fail data stored in the internal memory 235 and skips testing of the fail blocks. In this way, the testing section 230 can skip testing of fail blocks of the memory under test 10.

When not all of the memory regions have been tested, for example, the testing section 230 determines that the test to be performed is not yet finished (S350). Furthermore, the testing section 230 may stop or interrupt the testing in response to receiving a control command to stop or interrupt the testing. When the test to be performed is not yet finished, the testing section 230 reads the test information used to test the next block stored in the external memory 240, and updates the test information by writing this test information over the old test information in the internal memory 235 (S360). The testing section 230 repeats the processes of step S330 to step S350 for updating the test information and performing testing, until the test to be performed is finished.

With the test apparatus 100 according to the above embodiment, a plurality of memories under test 10 can be tested while a plurality of testing sections 230 transmit test information corresponding to the memory regions of the testing targets between the external memories 240 and the internal memories 235. In this way, the test apparatus 100 can test all memory regions of the memories under test 10 using the testing sections 230 that each have a capacity that is only sufficient to store the data for a partial memory region.

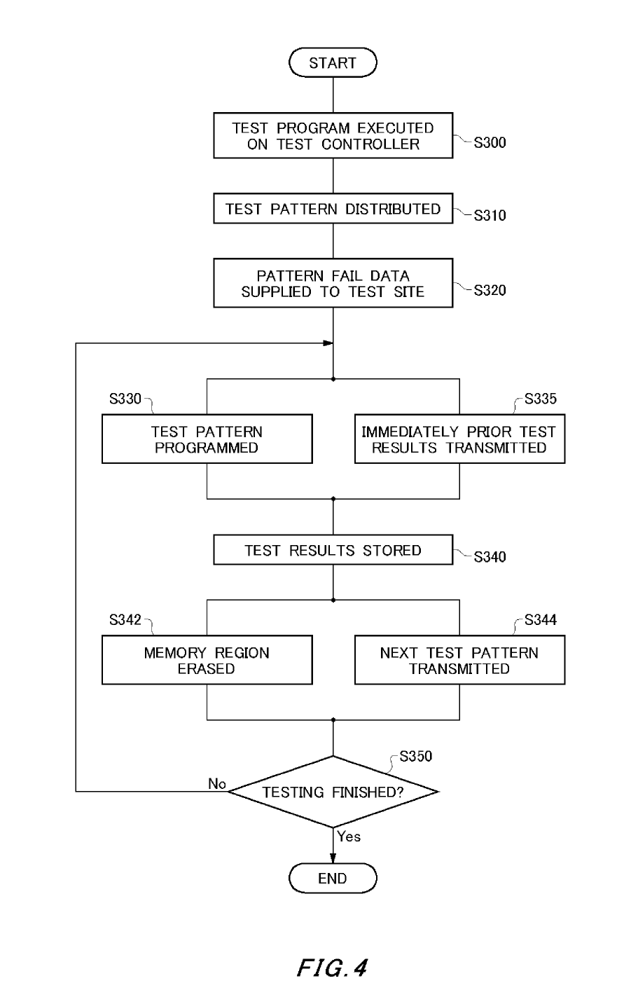

FIG. 4 shows a process flow of a modification of the test apparatus 100 according to the present embodiment. The test apparatus 100 of the present modification tests memories under test 10 that are memories such as flash memories requiring a large amount of time for the writing operation (programming) and/or deletion.

With a flash memory, it is not guaranteed that the writing of data will succeed at each address with one execution of the programming, and therefore the programming is executed a plurality of times. The number of times needed for the programming to succeed differs depending on the type of memory under test 10, and even differs according to each address in identical types of memories under test 10. Therefore, as a flash memory program test, the test apparatus 100 judges a memory under test 10 to be a pass when data is programmed in all of the memory cells to be programmed within a prescribed number of executions.

A data deletion test is performed in the same way, and the test apparatus 100 judges a memory under test 10 to be a pass when data is deleted from all of the memory cells from which data is to be deleted within a prescribed number of executions. The test apparatus 100 of the present embodiment efficiently performs the program test and/or data deletion test by performing the testing in parallel with other operations necessary for the testing. The process of the present modification is substantially the same as shown in FIG. 3 from step S300 at which the test program is executed to step S320 at which the pattern fail data is distributed to the testing sections 230, and therefore a description of these steps is omitted.

Each sub-controller 250 transmits test information in parallel between the external memory 240 and the internal memory 235, for at least one of a period during which the test data is being programmed in the partial memory region of the memory under test 10 and a period during which the partial memory region of the memory under test 10 is being erased. In the process flow of the present modification, each testing section 230 transmits the test results of a test executed immediately before from the internal memory 235 to the external memory 240 (S335), in a period during which the test pattern data is being programmed in the memory under test 10 (S330). The internal memory 235 stores the immediately prior test results, the pattern data, and expected value data used for the current testing.

Each testing section 230 stores the test results, which are pass/fail judgment results, corresponding to the partial memory region of the memory under test 10 (S340). The internal memory 235 may write the test results of the current test of the memory under test 10 over the information in the region where the test results of the test executed immediately therebefore are stored. The testing section 230 transmits the written test results from the internal memory 235 to the external memory 240 while the test pattern data for the next test is being programmed in the memory under test 10, and writes these new test results in the same region. In this way, each testing section 230 can sequentially transmit the test information during testing.

The process flow of the present modification is an example in which the immediately prior test results are transmitted while the test pattern data is being programmed in the memories under test 10, but instead, the external memories 240 may transmit the immediately prior test results while deleting the partial memory regions of the memory under test 10. With this process as well, the testing sections 230 can sequentially transmit the test information during testing.

Each sub-controller 250 transmits, between the external memory 240 and the internal memory 235, at least one of the test data corresponding to the next memory region and immediately prior test results of the memory region, for at least one of a period during which the test data is being programmed in the partial memory of the memory under test 10 and a period during which the partial memory region of the memory under test 10 is being erased. In the process flow of the present modification, each testing section 230 transmits the test pattern data corresponding to the next memory region from the external memory 240 to the internal memory 235 (S344) in a period during which the partial memory region of the memory under test 10 is being erased (S342).

Each internal memory 235 may write the test pattern data used for the next test of the memory under test 10 over the information in the region where the test pattern data executed immediately therebefore is stored. After the partial memory region of the memory under test 10 has been erased, the testing section 230 writes the next test pattern data over the information in the internal memory 235, and therefore the next test can be executed quickly.

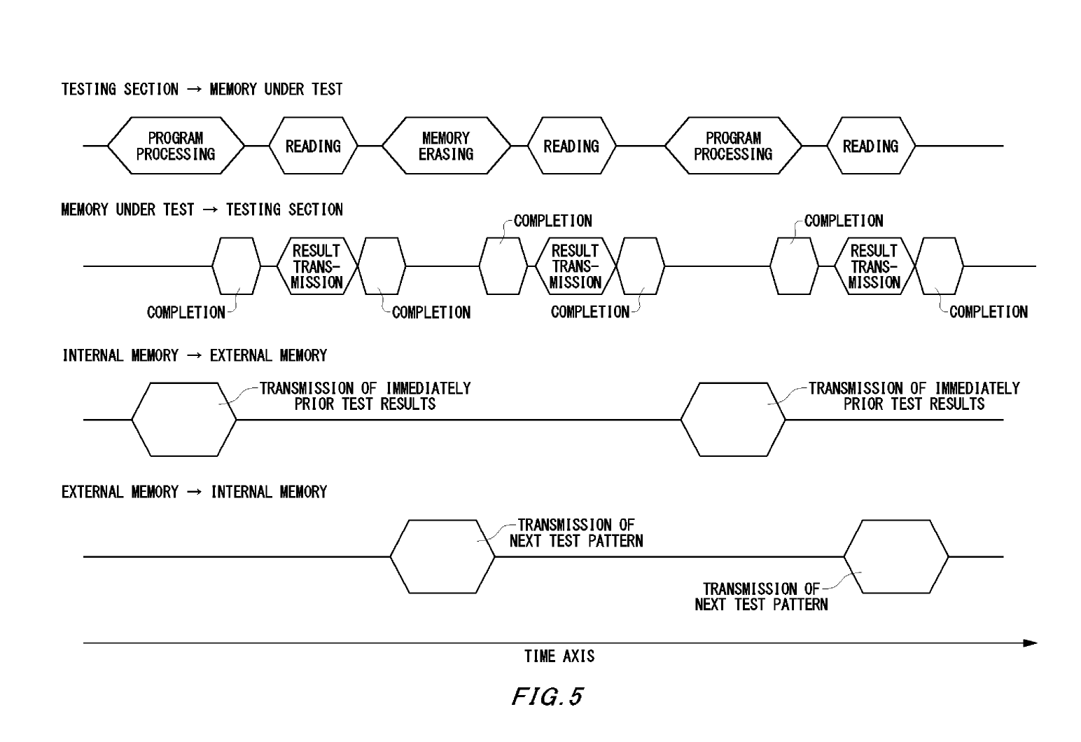

FIG. 5 shows timings of the processing in the present modification of the test apparatus 100 according to the present embodiment, with the time axis as the horizontal axis. FIG. 5 shows a control process performed on the memories under test 10 by the testing sections 230, a response process in which the testing sections 230 receive responses from the memories under test 10, a transmission process of transmission from the internal memories 235 to the external memories 240, and a transmission process of transmission from the external memories 240 to the internal memories 235.

Each testing section 230 performs a programming process to program test data in the corresponding memories under test 10. Here, the testing section 230 transmits to the memory under test 10 the test data based on the test pattern data stored in the internal memory 235. The testing section 230 may repeat the instructions for the process of transmitting and writing the data based on the test pattern data to the memory under test 10, until a predetermined data amount is reached, for example. While the instructions for the programming process are being provided, the testing section 230 transmits the test results of the immediately prior execution from the internal memory 235 to the external memory 240.

When the programming process is finished for a memory under test 10, the memory under test 10 notifies the testing section 230 that the process is finished. The memory under test 10 may repeat the data writing process and a verification process, until the programming process of the test data is completed. The testing section 230 instructs reading to the results of the programming in the memory under test 10, upon receiving notification that the programming process is finished.

Each memory under test 10 transmits to the testing section 230 the results read in response to the instructions from the testing section 230. Upon receiving the read test results, the testing section 230 compares the read results and the expected value data, and stores the comparison results in the internal memory. Next, the testing section 230 instructs the memory under test 10 to erase the memory of the memory under test 10. The testing section 230 transmits the test pattern data corresponding to the next memory region from the external memory 240 to the internal memory 235 while providing the instructions for the memory erasing.

When the memory erasing is finished for a memory under test 10, the memory under test 10 notifies the testing section 230 that the processing is finished. The memory under test 10 may repeat the memory erasing process and a verification process until a predetermined amount of memory has been erased, for example. The testing section 230 instructs the memory under test 10 to read the results of the memory erasing, in response to receiving notification that the memory erasing is finished.

Each memory under test 10 transmits the read results to the testing section 230, in response to the instructions from the testing section 230. Upon receiving the read results, the testing section 230 compares the results to the expected value data and stores the comparison results in the internal memory as the test results. The testing section 230 repeats the series of the program test and the memory erasing described above until testing is finished. In this way, the test apparatus 100 can sequentially transmit test information during testing.

The present modification is an example in which the subsequent pattern data is transmitted while the partial memory regions of the memories under test 10 are erased, but instead, the testing sections 230 may transmit the subsequent test pattern data while the test data is being programmed in the partial memory regions of the memories under test 10. With this process as well, the testing sections 230 can quickly perform the next test.

In the present modification described above, the testing sections 230 transmit the immediately prior test results and/or the subsequent test pattern data while testing is being performed. However, instead of or in addition to this, the testing sections 230 may transmit pattern fail data during testing. For example, the testing sections 230 may transmit the pattern fail data corresponding to the immediately prior test results between the external memories 240 and the internal memories 235, for at least one of a period during which the test data is being programmed in the partial memory regions of the memories under test 10 and a period during which the partial memory regions of the memories under test 10 are being erased. In this way, the testing sections 230 can sequentially transmit the test information during testing.

Furthermore, the testing sections 230 may transmit, between the external memories 240 and the internal memories 235, at least one of the pattern fail data corresponding to the next memory region and the pattern fail data corresponding to the immediately prior memory regions, for at least one of a period during which the test data is being programmed in the partial memory regions of the memories under test 10 and a period during which the partial memory regions of the memories under test 10 are being erased. In this way, the testing sections 230 can quickly execute the next test, while sequentially transmitting the test information during the testing.

In the above description, the testing sections 230 transmit the subsequent test pattern data and pattern fail data, for at least one of a period during which the test data is being programmed in the partial memory regions of the memories under test 10 and a period during which the partial memory regions of the memories under test 10 are being erased. But instead, the testing sections 230 may transmit the pattern fail data and the test pattern data to be used in the subsequent testing and onward, for at least one of a period during which the test data is being programmed in the partial memory regions of the memories under test 10 and a period during which the partial memory regions of the memories under test 10 are being erased.

In the test apparatus 100 according to the embodiments described above, the testing sections 230 access the external memories 240 via the sub-controllers 250 and transmit the test information between the external memories 240 and the internal memories 235. But instead, the sub-controllers 250 of the test apparatus 100 may access the internal memories 235 via the testing sections 230 and transmit the test information between the external memories 240 and the internal memories 235. The test apparatus 100 may sequentially transmit the test information by distributing the test information within the test sites 220.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a memory under test, comprising:
a testing integrated circuit device that tests the memory under test and includes an internal memory storing test information including at least one of a test result and test data for a partial memory region of the memory under test;
an external memory that stores the test information for an entire memory region of the memory under test; and
a memory controller that is connected to the external memory and transmits test information for a memory region of a test target between the external memory and the internal memory.

2. The test apparatus according to claim 1, wherein
the internal memory stores the test result for the partial memory region of the memory under test,
the memory controller acquires the test result for the partial memory region from the internal memory, and stores the test result in the external memory.

3. The test apparatus according to claim 1, wherein
the internal memory stores, as the test result, fail data indicating pass/fail of each address position corresponding to the partial memory region of the memory under test,
the memory controller reads the fail data corresponding to the memory region of the test target from the external, and transmits the fail data to the internal memory,
the testing integrated circuit device tests the memory region of the test target and updates the fail data stored in the internal memory, and
the memory controller acquires the updated fail data from the internal memory and stores the updated fail data in the external memory.

4. The test apparatus according to claim 1, wherein
the external memory stores block fail data indicating pass/fail of each block of the memory under test,
the memory controller reads the block fail data of a block serving as the test target from the external memory, and transmits the block fail data to the internal memory, and
the testing integrated circuit device identifies a fail block in which a fail has already been detected from the block fail data stored in the internal memory, and skips testing of the fail block.

5. The test apparatus according to claim 1, wherein
the memory under test is a flash memory, and
the memory controller transmits the test information between the external memory and the internal memory for at least one of a period during which the test data is being programmed to the partial memory region of the memory under test and a period during which the partial memory region of the memory under test is being erased.

6. The test apparatus according to claim 5, wherein
the memory controller transmits, between the external memory and the internal memory, at least one of the test data corresponding to a subsequent memory region and the test result of an immediately prior memory region, for the at least one of the period during which the test data is being programmed to the partial memory region of the memory under test and the period during which the partial memory region of the memory under test is being erased.

7. The test apparatus according to claim 1, comprising:
a plurality of test sites that each include one of the testing integrated circuit devices, one of the external memories, and one of the memory controllers; and
a test controller that is connected to the memory controller of each test site and controls testing by the test sites.

8. The test apparatus according to claim 7, wherein
the memory controller in each test site transmits the test information between the test controller and the corresponding external memory.

9. A method for testing a memory under test, comprising:
testing the memory under test and including an internal memory storing test information that includes at least one of a test result and test data for a partial memory region of the memory under test;
storing the test information for an entire memory region of the memory under test in an external memory; and
connecting to the external memory and transmitting test information for a memory region of a test target between the external memory and the internal memory.
